(19) United States
(12) Patent Application Publication
(10) Pub. No.: US 2026/0074153 A1
(43) Pub. Date: Mar. 12, 2026

(54) System and Method for Atomic Layer Etching and Radical-Based Highly Selective Etching in a Single Process Chamber

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/829,291

(22) Filed: Sep. 10, 2024

(51) Int. Cl. H01J 37/32; C23C 14/34

(52) U.S. Cl. CPC H01J 37/32422; C23C 14/345; H01J 37/32091; H01J 37/321; H01J 37/32449; H01J 2237/3341; H01J 2237/3346

(57) ABSTRACT

Disclosed herein is a system and method for integrating atomic layer etching (ALE) and radical-based highly selective etching (HSE) within a single process chamber. The innovative design, featuring a grounded ion filter (GIF), enables the precise control of ions and neutrals during etching. The system improves process efficiency, enhances selectivity, and reduces cycle times, making it ideal for manufacturing high-performance semiconductor devices with complex, high aspect ratio structures.

### BACKGROUND OF THE INVENTION

### 1. Field of the Invention

The present invention pertains to the field of semiconductor manufacturing, specifically focusing on methods and apparatus designed to optimize both atomic layer etching (ALE) and radical-based highly selective etching (HSE) processes within a single process chamber.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{{vE}_{i} {J}_{i}}{1 + ( {vE}_{i} {J}_{i} ) / ( {v}_{n} {sJ}_{n} )} , \qquad [ 2 ]$$

where υ represents the volume removed per unit bombardment energy for a saturated surface (cm³/eV), E; the ion energy (eV), Jᵢ the ion flux to the surface (cm²/s), υₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of Inductive Coupled Plasma (ICP) or Transformer Coupled Plasma (TCP). Additionally, gas injection techniques have improved, incorporating multiple injection points to ensure a uniform plasma within the vacuum reactor, as described in U.S. Pat. No. 8,231,799 to Bera et al. and U.S. Pat. No. 10,825,659 to Treadwell. Further enhancements include optimizing the electrostatic chuck (ESC) to feature multiple zones with independently adjustable temperatures (U.S. Pat. No. 9,713,200 to Pease and U.S. Pat. No. 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and U.S. Pat. No. 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy. Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for Critical Dimension (CD), loading, and profile remains a significant challenge, often entailing considerable expense.

Plasma enhanced ALE (simply as ALE throughout this disclosure) has been developed to address the limitations of RIE. ALE apparatus has evolved from the RIE apparatus with less stringent requirements for achieving uniformity on a 300 mm wafer. However, ALE has unique requirements due to the nature of its process steps, detailed herein.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE or plasma enhanced ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al.,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process—characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \% , \qquad [ 2 ]$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus, it may increase the cost of the process.

Another solution to this problem, as disclosed in U.S. Pat. No. 10,014,192 to Singh, involves using a chamber that is divided into a plasma-generating region and a substrate-processing region by a separating plate structure. This plate structure blocks ions from reaching the substrate while utilizing low-energy metastable species to etch the substrate. However, due to the complete elimination of high-energy ions in the processing region, Singh's method is ineffective for etching high aspect ratio (HAR) structures. In such structures, high-energy ions are essential for reaching the bottom of deep or narrow features. Without sufficient ion energy, the etching process lacks the directional control needed to effectively etch HAR features.

The present invention addresses this issue by introducing an improved chamber design that suppresses ion generation during the surface modification step of the ALE process while allowing high-energy ions to be produced near the substrate during the sputtering step. These ions are used to precisely etch high aspect ratio (HAR) structures. This method enhances control over the etching process, improving the quality and consistency of the resulting semiconductor devices. This approach represents a significant advancement in semiconductor fabrication, enabling the production of smaller, more complex, and higher-performing electronic devices.

Moreover, the ALE process can be followed by a radical-based highly selective etching (HSE) process. Traditionally, these processes are conducted in separate chambers. Plasma-enhanced ALE anisotropically removes material from a substrate, while radical-based HSE removes material isotropically. In certain cases, post-ALE surfaces are sensitive to air exposure, which can cause oxidation and lead to defects. Additionally, integrating ALE and HSE within a single chamber could reduce cycle time and overall process costs.

Thus, there is a need for an improved method and apparatus that addresses these challenges, ensuring ALE process ideality while enhancing the performance and cost-efficiency of both ALE and radical-based HSE processes. This invention proposes a novel chamber design with various embodiments to meet this need.

### SUMMARY

The invention provides a system and method for optimizing ALE and radical-based HSE processes. All embodiments integrate ALE and HSE within a single plasma process chamber, improving cycle time and overall performance.

The chamber includes an upper chamber, and a lower chamber separated by a grounded ion filter (GIF). The GIF allows neutral species, such as radicals, to pass between the upper and lower chambers while blocking ions. This design ensures surface modification of the substrate without ion bombardment, thereby improving the ideality of the ALE process.

One aspect of the invention involves configuring the upper chamber as an inductively coupled plasma (ICP) reactor during the surface modification step of ALE, while the lower chamber operates as a capacitively coupled plasma (CCP) reactor during the sputtering step. This dual functionality aids in removing modified surface layers, further enhancing the ideality of the ALE process.

Additionally, in certain implementations, the upper chamber operates as an ICP reactor, and the lower chamber functions as a radical reactor during the radical-based HSE step. The GIF blocks ion penetration during this step, allowing only neutral species to reach the substrate, thereby improving the selectivity of the etching process.

Some embodiments incorporate various implementations for introducing gas or vaporized precursors into the chamber, such as internal gas/precursor distribution units or showerheads, to optimize the efficiency of gas or precursor delivery.

Furthermore, during the sputtering step of ALE, the invention provides a tailored waveform generated by the bias unit to neutralize trapped positive ions and maintain a stable bias voltage. This is critical for generating ions with narrowly defined energy distributions, essential for forming structures with high aspect ratios.

The novel chamber design is proposed for two applications:
1. Etching a targeted layer using the ALE process to from a pattern, followed by removing the mask layer in the same chamber through a radical-based HSE process.
2. Etching a high aspect ratio structure using the ALE process, followed by selective lateral etching of one of the layers in the stack.

### BRIEF DESCRIPTIONS OF THE DRAWINGS

In order to provide enhanced clarity, the following description references the accompanying drawings:

FIG. 1A illustrates an exemplary plasma processing chamber partitioned into an upper and lower section by a GIF.

FIG. 1B presents a top-view depiction of the GIF.

FIG. 1C provides a detailed view of an exemplary design for the GIF.

FIG. 2 depicts various alternative embodiments and designs of the GIF.

FIG. 3A illustrates an exemplary operating mode of the chamber.

FIG. 3B highlights the functionalities of the upper and lower chambers during ALE and HSE processes, respectively.

FIG. 4A showcases a first implementation for the introduction of gas/precursor into the lower chamber through a first gas/precursor distribution unit.

FIG. 4B showcases a second implementation for the introduction of gas/precursor into the lower chamber through a version of the second gas/precursor distribution unit.

FIG. 4C showcases a third implementation for the introduction of gas/precursor into the lower chamber through another version of the second gas/precursor distribution unit.

FIG. 4D showcases a fourth implementation for the introduction of gas/precursor into the lower chamber through yet another version of the second gas/precursor distribution unit.

FIG. 5A illustrates a schematic flow for the etching of a layer to from a pattern, including in-situ mask layer removal.

FIG. 5B delineates a step-by-step flowchart describing the operations of the system for etching the layer, including in-situ mask layer removal.

FIG. 6A illustrates a schematic flow of a process for etching an HAR structure, including selectively removing a material from the stack.

FIG. 6B delineates a flowchart describing the operations of the system for etching an HAR structure, including selectively removing a material from the stack.

### DETAILED DESCRIPTIONS

To ensure comprehensive understanding, this section delves into detailed embodiments of the present invention. Although specific details are provided for clarity, modifications and variations that align with the subsequent claims are considered within the scope of this disclosure. Conventional methods and components are highlighted to emphasize the distinct features of the invention.

### Terms Used in this Disclosure are Defined as Follows

Aspect Ratio: The ratio of the height to the width of a feature on a semiconductor wafer, critical in defining the geometry and performance of microstructures.
Bias Unit: A component that generates plasma or applies a controlled voltage to accelerate ions towards the wafer held by an electrostatic chuck (ESC), creating an electric field that enhances ion bombardment. This is essential for controlling ion energy and directionality in etching processes. In a CCP reactor, the bias unit can also be used to generate a plasma in the reactor.
Chamber: An enclosed environment within process equipment where semiconductor manufacturing processes, such as etching or deposition, occur.
Chuck: A component that holds and secures the wafer in place during semiconductor manufacturing processes.
Electrostatic Chuck (ESC): A type of chuck using electrostatic forces to secure the wafer during semiconductor processes, ensuring uniform clamping and stability.
Gas/Precursor Distribution Unit: A component designed to introduce and distribute gases or precursors across a substrate in a vacuum chamber. It may include an injector placed centrally or at specific angles, or a showerhead with a perforated plate to disperse gases. Side injection mechanisms promote lateral flow.
Gas/Precursor Source: The origin or supply point of process gases or precursors, typically connected to a centralized gas distribution system, ensuring proper gas composition and flow conditions in the process chamber. For precursors, vaporization units are commonly employed.
Grounded Ion Filter (GIF): A conductive plate dividing a vacuum chamber into upper and lower chambers. It allows neutrals to pass while blocking ions. The GIF includes openings designed for blocking the ions.
High Aspect Ratio (HAR): Features with a significantly greater height than width, posing challenges in maintaining uniformity and precision during manufacturing.
Highly Selective Etching (HSE): A radical-based etching process utilizing reactive radicals generated in plasma to selectively remove material layers with minimal impact on underlying or adjacent layers.
Lower Chamber: The lower section of a vacuum chamber, functioning as a CCP reactor during the sputtering step of ALE and as a radical reactor during radical-based HSE.
Plasma Enhanced ALE (or ALE): An atomic-level etching process that removes material layer by layer, offering precise control over etch depth and profile. It involves surface modification followed by physical ion bombardment to ensure high selectivity and precision.
Plasma Process Chamber: A vacuum chamber specifically designed for plasma-based processes, such as etching and deposition, where plasma activates chemical reactions or removes material from the wafer surface.
Plasma Source: A device that generates plasma for semiconductor processes, including inductively coupled plasma (ICP), transformer coupled plasma (TCP), and capacitively coupled plasma (CCP).
Process System: The equipment and machinery integrated for performing various semiconductor processes such as deposition, etching, or cleaning.
Reactive Ion Etching (RIE): A plasma-based etching technique where both ion bombardment and chemical reactions synergistically remove material from a substrate, offering precise control over etching.
Resonator: A device designed to resonate at a specific frequency, commonly used for RF impedance matching in circuits.
RF Power Generator: A device that produces radio frequency power for energizing plasma in processes like etching or deposition.
Sheath: The boundary layer between plasma and a surface, controlling the energy and flux of ions and electrons reaching the surface, critical for etching and deposition.
Substrate: The base material, typically a silicon wafer, upon which semiconductor devices are fabricated.
System Controller: The central unit responsible for managing and controlling the various operations and parameters of semiconductor manufacturing systems.
Tailored Waveform Generator: A device that generates custom electrical waveforms to optimize plasma processes by controlling plasma characteristics, improving process uniformity and selectivity. The tailored waveform generator can be designed as a part of a bias unit to improve ion energy distribution.
Transmission Line (RF): A specialized conductor designed to carry radio frequency signals with minimal loss, used to efficiently transfer RF power from the generator to the plasma source in semiconductor processes.
Upper Chamber: The upper section of a vacuum chamber, operating as an ICP reactor during ALE surface modification and radical-based HSE process.
Vacuum Chamber: An enclosed environment where air and gases are removed to create a low-pressure atmosphere, used in processes requiring precise atmospheric control.
Window: A non-conductive, transparent or semi-transparent barrier in a vacuum chamber that allows electromagnetic waves to pass through for plasma generation without exposing external components.

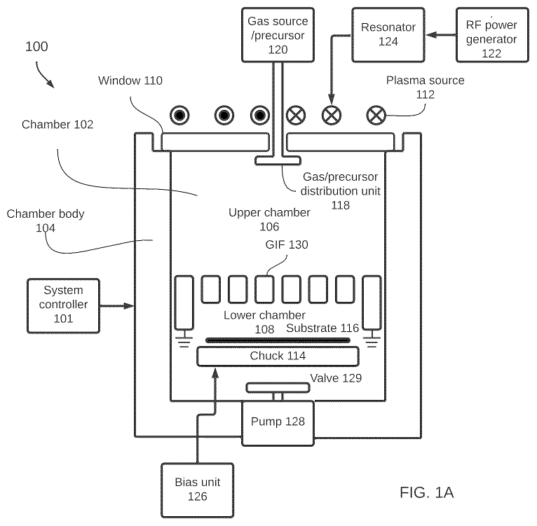

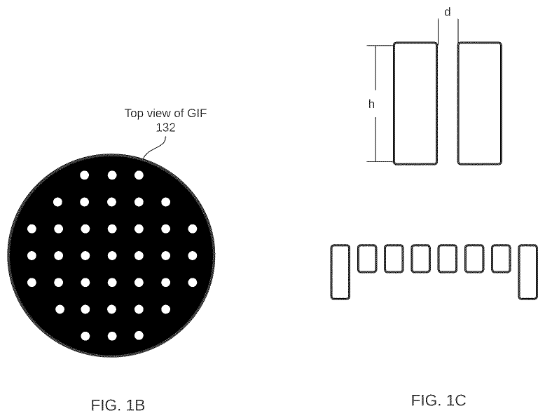

FIG. 1A illustrates an exemplary process system, referred to as 100, which incorporates a plasma process chamber 102. The operations within the chamber 102 are managed by a system controller 101. The chamber 102 is enclosed by a chamber body 104, creating a vacuum environment suitable for plasma processing. Positioned on top of the chamber body 104 is a window 110, which hermetically seals the vacuum chamber 102. In certain embodiments, the window is made of quartz, while in other embodiments, it is made from ceramic materials.

Above the window 110 is a plasma source 112, which, as shown in FIG. 1A, consists of a three-turn coil. However, the coil may vary in the number of turns depending on specific operational needs, and multiple coils may also be used. Although FIG. 1A depicts a flat coil, other configurations, such as cylindrical or conical, are also within the scope of the invention.

The plasma source 112 is connected to a radio frequency (RF) power generator 122 via a resonator 124. The RF power generator 122 is capable of producing RF power at one or more frequencies, including but not limited to 100 kHz, 400 kHz, 2 MHz, 13.56 MHz, and 60 MHz. The resonator 124 matches the output impedance of the RF power generator 122 with the plasma load in the chamber 102, accounting for the effects of transmission lines, as is standard practice.

As shown in FIG. 1A, a first gas/precursor distribution unit 118 connects with a gas/precursor source 120 through an aperture in the window 110. It is essential to maintain a hermetic seal around this aperture to preserve the vacuum integrity of the chamber 102. The gas/precursor source 120 may include separate units for delivering gas and precursor. The gas delivery system could consist of a gas box, while the precursor delivery system may use a vaporized liquid or solid precursor delivery system, or a vaporizer. The gas/precursor distribution unit 118 can take the form of either an injector or a showerhead, depending on the embodiment. In an alternative embodiment, the window 110 may integrate with the gas/precursor distribution unit 118, functioning as a showerhead while simultaneously sealing the vacuum chamber. In some embodiments, the gas/precursor distribution unit 118 may also enable lateral gas introduction into the chamber 102.

Within the chamber 102, there is a chuck 114 that supports a substrate 116. The chuck 114 can be configured as an electrostatic chuck (ESC) or a vacuum chuck, among other designs.

The chamber 102 is divided into an upper chamber 106 and a lower chamber 108 by a GIF 130. Positioned parallel to the substrate 116, the GIF 130 is made of conductive materials such as aluminum or silicon. For enhanced erosion resistance, the aluminum may undergo anodization.

The GIF 130 can be grounded either through the chamber body 104 or other grounded structures in the chamber, such as liners (not shown).

The upper chamber 106 functions as an inductively coupled plasma (ICP) chamber. Plasma ignition in the upper chamber produces electrons, ions, and neutral species. The GIF 130 acts as a barrier, preventing ions from passing through while allowing neutral species to flow through the openings in the GIF 130. The neutrals include chemically reactive radicals. FIG. 1B provides a top view of the GIF 130, showing an example of an opening 132. As shown in FIG. 1C, each opening has a diameter d and a height h. To effectively block ions, the openings must have a small diameter and a high aspect ratio h/d. The height of the openings can range from 0.1 mm to 10 mm, with aspect ratios varying from 10 to 500.

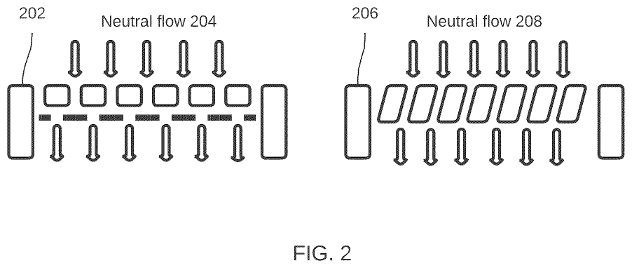

Several variations of the GIF 130 are possible. FIG. 2 illustrates two such examples. In the first example 202, the neutral-conducting channels in the GIF 130 consist of a first group of vertical holes, horizontal conducting channels connected to these holes, and a second group of vertical holes connected to the horizontal channels. The second group of holes is intentionally misaligned with the first group, ensuring that ions are blocked while neutral species can pass through the GIF 130 (see neutral flow 204).

In the second example 206, the openings in the GIF 130 are angled relative to the vertical axis. This design prevents ions from passing through the angled openings while allowing neutral species to diffuse through (see neutral flow 208).

It is important to note that these designs are illustrative and not exhaustive. The openings in the GIF 130 are not limited to circular shapes and may take on various forms, including square, rectangular, elliptical, hexagonal, or octagonal. The sizes, depths, and distribution of the openings may vary, and they can be uniform or non-uniform. Additionally, the thickness of the GIF 130 may also vary. Various methods for blocking ions fall within the scope of this invention, including multiple horizontal channels or angled openings, either separately or in combination.

As shown in FIG. 1A, during the surface modification step of the ALE process, the upper chamber 106 functions as an ICP chamber. After plasma ignition, electrons migrate toward the GIF 130 and chamber body 104. Since the GIF 130 is grounded and lacks a blocking capacitor, the plasma sheath on its surface will be very thin. This minimizes ion penetration through the GIF 130 openings, thus extending its operational life and reducing ion bombardment.

During the sputtering step of the ALE process, the lower chamber 108 functions as a capacitively coupled plasma (CCP) chamber. In this configuration, the GIF 130 serves as the grounded electrode, while the chuck 114 acts as the powered electrode. In one embodiment, the chuck 114 is powered by RF energy from a bias unit 126 through a resonator (not shown), with frequencies ranging from 100 kHz to 100 MHz. In another embodiment, the bias unit 126 supplies RF power at multiple frequencies, including but not limited to 100 kHz, 400 kHz, 1 MHz, 2 MHz, 13.56 MHz, and 60 MHz. The bias unit 126 establishes a bias on the chuck 114 and can also initiate plasma in the lower chamber 108. In CCP mode, plasma density is typically lower than in ICP mode but increasing the RF frequency from the bias unit 126 can raise plasma density. In some embodiments, a tailored waveform may additionally be used to achieve a more precise ion energy distribution.

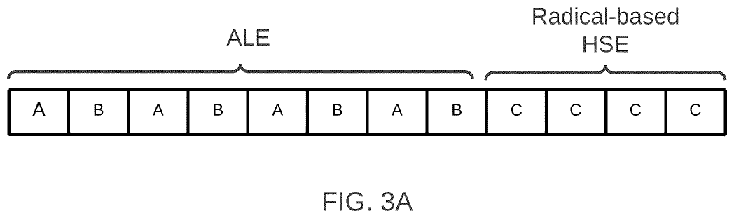

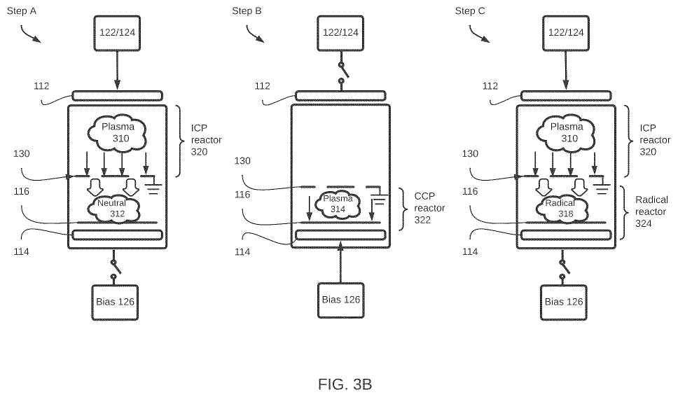

FIG. 3A shows an exemplary process sequence using the plasma process chamber 100. The process begins with an ALE process, consisting of multiple cycles of a surface modification step A and a sputtering step B, followed by several cycles of a radical-based HSE step C. FIG. 3B illustrates the operating modes of chamber 102 for steps A, B, and C.

During the surface modification step A of the ALE process, a first process gas is introduced from the gas/precursor source and distribution units 120 and 118. The plasma source 112 receives RF power from the RF power generator 122 through the resonator 124, generating plasma 310 in the upper chamber 106, which functions as an ICP reactor 320. The ions in the plasma 310 are blocked by the GIF 130, allowing neutrals 312, including radicals, to diffuse through the GIF's openings and modify the surface of substrate 116. During step A, the bias unit 126 does not provide a bias to the chuck 114 to prevent ion generation in the lower chamber 108.

In the sputtering step B of the ALE process, the bias unit 126 supplies RF power to the chuck 114, converting the lower chamber 108 into a CCP reactor 322. An inert gas, such as argon, is introduced through an internal gas/precursor distribution unit, denoted as the second gas/precursor distribution unit. Subsequently, an argon plasma 314 is generated between the GIF 130 and substrate 116. Positive argon ions are accelerated towards the substrate by the electric field, removing the modified surface layer.

During the radical-based HSE step C, plasma 310 is generated similarly to step A, but with different gases or precursors for selective etching. The gas or precursor includes halogen, oxygen, hydrogen, and carbon-fluorine compounds. Ions in the plasma are blocked by the GIF 130, while radicals 318 diffuse into the lower chamber 108, which acts as a radical reactor 324. The chuck 126 is not biased in this step to avoid ion generation, which would reduce etching selectivity.

The innovative chamber design, illustrated in FIG. 1A, enables efficient execution of both ALE and radical-based HSE processes. The chamber's structure, particularly the separation of the upper and lower chambers and the use of the GIF 130 to control ion and neutral flow, ensures that each process step operates under optimal conditions. This design allows for precise control over film etching on the substrate 116, leading to higher-quality and more reliable semiconductor devices.

By effectively managing the functionalities of the upper and lower chambers, this invention addresses the challenges faced in conventional ALE and radical-based etching. For instance, in the ALE process, the separation of chambers prevents ion bombardment during the surface modification step A, a critical factor for achieving optimal ALE results. During sputtering step B, the CCP reactor generates energetic ions with enhanced directionality, facilitating the removal of modified layers from high aspect ratio structures, thereby improving ALE performance.

Moreover, the use of a tailored waveform in the bias unit 126 further enhances process precision by generating ions with narrowly defined energy distributions, essential for forming high aspect ratio structures.

During the radical-based etching process, the chamber's design ensures effective delivery of radicals to the lower chamber without ion interference, enabling high-performance HSE. Overall, this chamber design supports the execution of ideal ALE and radical-based etching processes within a single chamber.

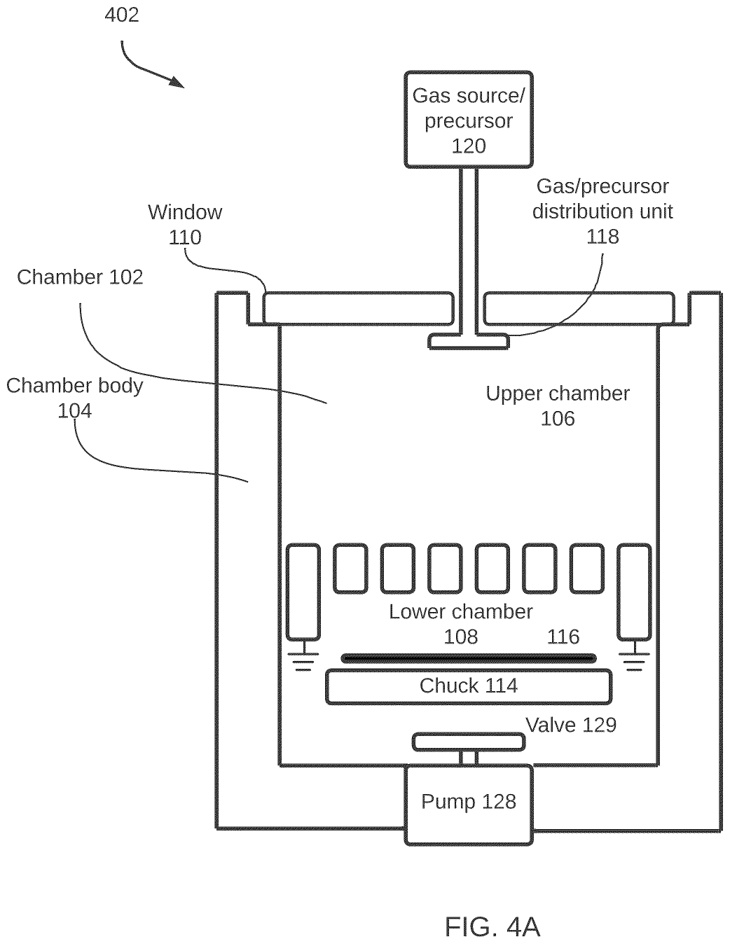

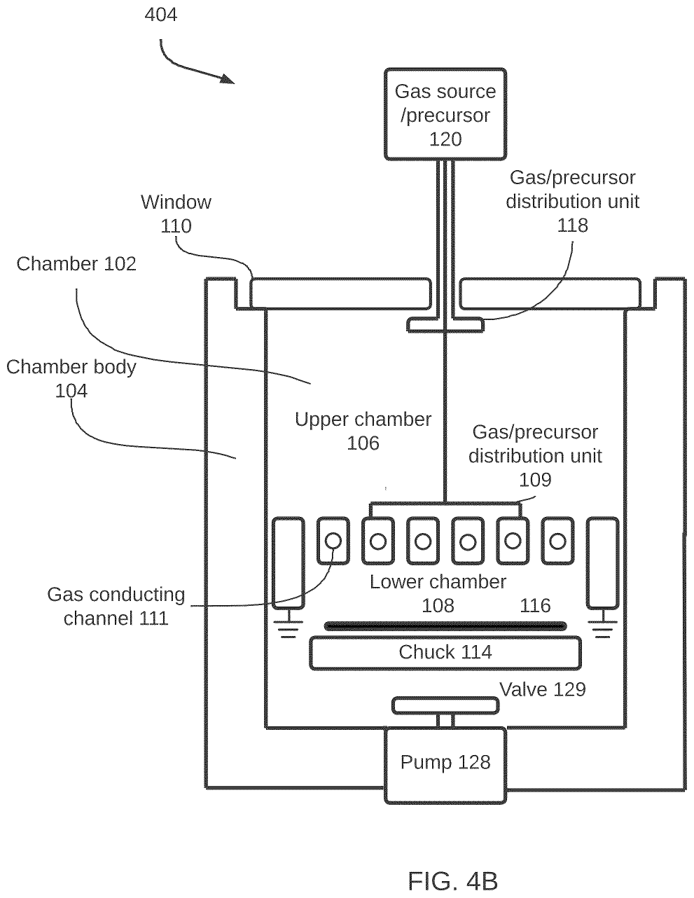

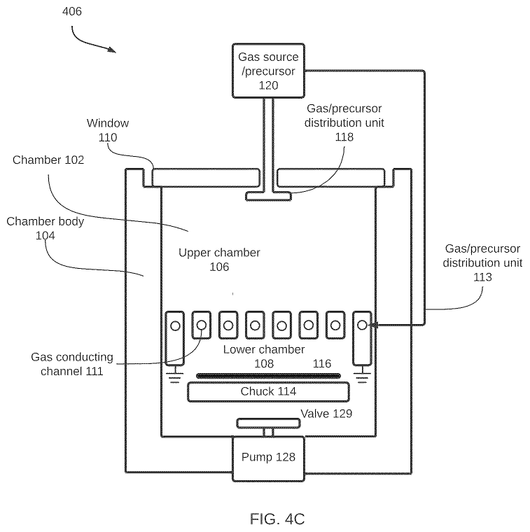

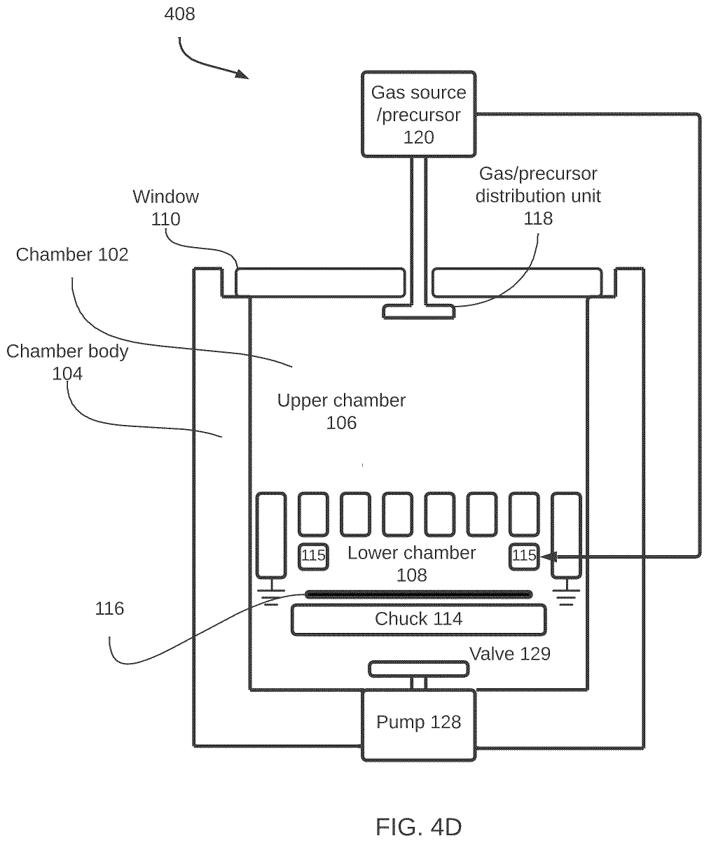

FIG. 4 shows various ways to introduce the gas used in the sputtering step B. In one configuration (402), argon flows from the gas source 120 to the upper chamber 106 via the gas/precursor distribution unit 118, then diffuses into the lower chamber 108 through the GIF 130 openings. Another configuration (404) uses the GIF 130 as a showerhead, with an internal distribution unit 109 directing argon straight into the lower chamber. In a third configuration (406), argon is delivered through an internal distribution unit 113 located at the side of the GIF 130, ensuring even distribution. In a fourth configuration (408), argon is injected directly into the lower chamber 108 from a distribution unit 115 below the GIF. The internal gas/precursor distribution unit is also called as the second gas/precursor distribution unit. These configurations are illustrative, and other variations may fall within the scope of the invention.

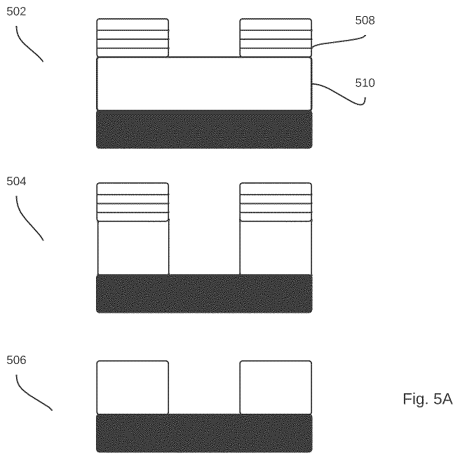

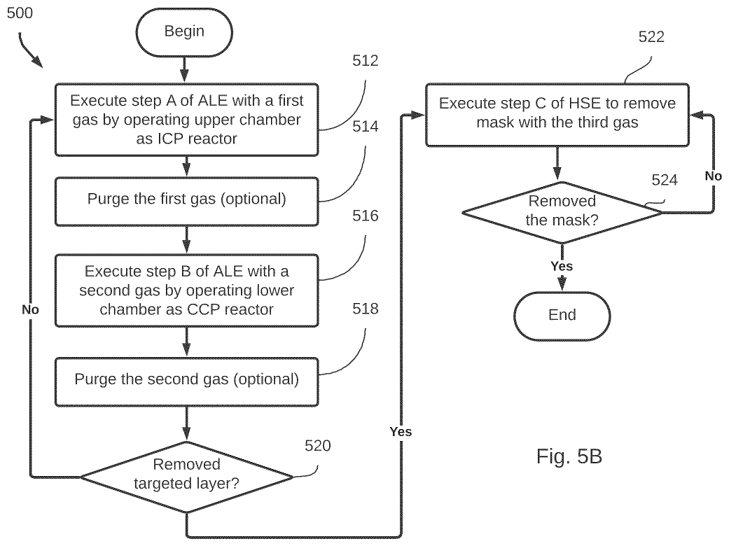

FIG. 5A illustrates a schematic flow for a process involving the etching of a layer and in-situ mask removal. A substrate 502 is introduced with a deposited mask layer 508 and a target layer 510 to be etched using ALE. The mask layer 508 can be a photoresist layer, potentially enhanced with transfer layers or including a hard mask, such as a carbon layer. In general, the mask materials can include one or a combination of the following materials: carbon, metal-doped carbon, silicon, silicon nitride, silicon oxide, photoresist, titanium nitride.

FIG. 5B provides a step-by-step flowchart for the process 500. In step 512, a first process gas is introduced into the upper chamber 106 (operated as an ICP reactor 320) through the first gas/precursor distribution unit 118, and neutrals, including radicals, diffuse into the lower chamber 108, completing the surface modification step A. In step 514, the chamber may optionally be purged before introducing a second process gas using one of the configurations shown in FIGS. 4A-D. In step 516, the lower chamber 108 operates as the CCP reactor 322, and the sputtering step B removes the modified surface layer. In step 518, the chamber is optionally purged before returning to step A for additional ALE cycles. Step 520 involves the system controller evaluating whether the ALE process is complete, resulting in the structure 504.

In step 522, a third process gas or precursor is introduced to perform radical-based HSE, removing the mask layer 508. The upper chamber 106 acts as the ICP reactor 320, while the lower chamber functions as the radical reactor 324. This process enables selective in-situ mask removal with high selectivity. Step 524 involves the system controller 101 confirming mask removal, producing the structure 506.

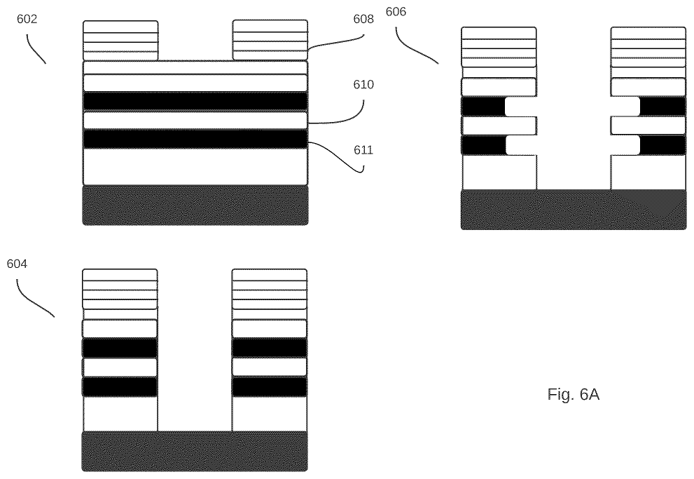

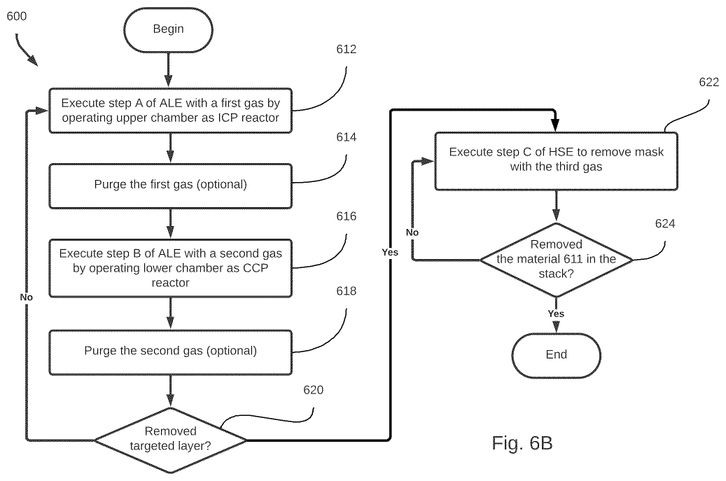

FIGS. 6A and 6B illustrate a second example using the process system 100 for high aspect ratio (HAR) etching. In FIG. 6A, a substrate 602 with a mask layer 608 and target layers 610 and 611 is introduced. This structure may represent a 3D NAND stack with layers of silicon oxide and silicon nitride.

FIG. 6B outlines the process flow 600. Step 612 involves introducing a first process gas into the upper chamber 106 (operated as an ICP reactor 320), where neutrals diffuse into the lower chamber 108 to complete the surface modification step A. Step 614 optionally purges the chamber before introducing a second process gas for step B of the ALE process, using one of the configurations in FIGS. 4A-D. Step 616 involves operating the lower chamber as the CCP reactor 322 to remove the modified surface layer. Step 618 purges the chamber before repeating the ALE cycles. Step 620 allows the system controller to determine if the ALE process is complete, resulting in the structure 604.

In step 622, a third process gas or precursor is introduced to perform radical-based HSE, selectively removing one of the two layers in the stack. The upper chamber operates as the ICP reactor 320, and the lower chamber as the radical reactor 324. In step 624, the system controller 101 checks whether the lateral etching is complete, producing the structure 606, with the layer 611 partially or fully removed, depending on the requirements.

1. A process chamber for performing ALE and radical-based HSE processes, comprising:
an upper chamber and a lower chamber separated by a GIF;
a plasma source, connected to a first RF power generator, configured to generate an inductively coupled plasma in the upper chamber;
a bias unit comprising at least a second RF power generator, connected to a chuck, configured to generate a capacitively coupled plasma in the lower chamber;
a first gas/precursor distribution unit configured to deliver a gas or a precursor into the upper chamber;
a second gas/precursor distribution unit configured to deliver a gas or a precursor into the lower chamber;
a system controller configured to:
operate the chamber in a surface modification step of an ALE process, wherein the plasma source generates the inductively coupled plasma in the upper chamber, wherein the GIF blocks ions in the plasma from entering the lower chamber while allowing neutrals entering the lower chamber to modify the substrate surface;
operate the chamber in a sputtering step of the ALE process, wherein the bias unit generates the capacitively coupled plasma in the lower chamber, wherein the ions in the plasma are accelerated by a voltage bias caused by the bias unit to remove the modified layer; and
operate the chamber for a radical-based HSE process, wherein the plasma source generates an inductively coupled plasma in the upper chamber, the GIF blocks ions from the plasma from entering the lower chamber while allowing neutrals from the plasma to modify the substrate surface and remove the modified layer.

2. The chamber of claim 1, wherein a gas is introduced into the upper chamber through the first gas/precursor distribution unit during the surface modification step of the ALE process, wherein the gas further includes a halogen.

3. The chamber of claim 1, wherein an inert gas is introduced into the lower chamber through the second gas/precursor distribution unit during the sputtering step of the ALE process.

4. The chamber of claim 1, wherein a gas or a precursor is introduced into the upper chamber through the first gas/precursor distribution unit during the radical-based HSE process.

5. The chamber of claim 1, wherein the ALE process further comprises a purge step, controlled by the system controller, between the surface modification and the sputtering steps, or between the sputtering and the surface modification steps.

6. The chamber of claim 1, wherein a combined ALE and radical based HSE process further comprises a purge step, executed by the system controller, between the ALE and the HSE steps, or between the HSE and the ALE steps.

7. The chamber of claim 1, wherein the ALE process and the radical-based HSE processes are performed in cycles, and the HSE cycles may be inserted into a sequence of ALE cycles, or ALE cycles may be inserted into a sequence of HSE cycles.

8. The chamber of claim 1, wherein the openings in the GIF are dimensioned and configured to minimize ion leakage through the openings.

9. The chamber of claim 1, wherein the openings in the GIF are oriented at an angle relative to the vertical direction with respect to the substrate surface.

10. The chamber of claim 1, wherein the openings in the GIF comprise a first set of openings, horizontal conducting channels connected to the first set of openings, and a second set of openings connected to the horizontal conducting channels, wherein the openings in the second set are misaligned from the openings in the first set.

11. The chamber of claim 1, wherein the plasma source is deactivated during the sputtering step of the ALE.

12. The chamber of claim 1, wherein the bias unit is deactivated during the surface modification step of the ALE or the HSE process.

13. The chamber of claim 11, wherein the bias unit further includes a tailored waveform generator.

14. A method for processing a substrate, the method comprising:
providing a plasma process chamber, comprising an upper chamber and a lower chamber separated by a GIF, wherein the chamber further comprising a plasma source configured to generate an inductively coupled plasma in the upper chamber, a bias unit, connected to a chuck, for generating a capacitively coupled plasma in the lower chamber, a first gas/precursor distribution unit, and a second gas/precursor distribution unit;
performing by a system controller an ALE process, comprising:
operating the chamber in a surface modification step, wherein the plasma source generates the inductively coupled plasma in the upper chamber, wherein the GIF blocks ions from the plasma from entering the lower chamber while allowing neutrals entering the lower chamber to modify the substrate surface;
operating the chamber in a sputtering step, wherein the bias unit generates the capacitively coupled plasma in the lower chamber, wherein the ions in the plasma are accelerated by a voltage bias caused by the bias unit to remove the modified layer; and
performing by the system controller a radical-based HSE process, comprising:
operating the chamber for the radical-based HSE process, wherein the plasma source generates an inductively coupled plasma in the upper chamber, the GIF blocks ions from the plasma from entering the lower chamber while allowing neutrals from the plasma to modify the substrate surface and remove the modified layer.

15. The method of claim 14, wherein the ALE process and the HSE processes are performed in cycles, and the HSE cycles may be inserted into a sequence of ALE cycles, or ALE cycles may be inserted into a sequence of HSE cycles.

16. The method of claim 14, wherein the ALE process is employed to form a high aspect ratio structure including a stack of a plurality of materials and the radical-based HSE is used to remove one of the materials after the ALE process, wherein the aspect ratio ranges from 5 to 300.

17. The method of claim 14, wherein the ALE process is employed to form a pattern with a mask including one or a more layers of materials and the radical-based HSE is used to remove said one or more layers.

18. A method of forming a pattern on a substrate, the method comprising:
providing a plasma process chamber comprising an upper chamber and a lower chamber separated by a GIF, the chamber further comprising a plasma source configured to generate a plasma in the upper chamber, a bias unit operatively connected to a chuck in the lower chamber, a gas distribution unit, and a controller;
receiving a substrate with a defined layer of mask on top of a targeted layer material to be etched, wherein said layer of mask further includes one or more materials;
performing an ALE process to etch the stack of the materials, comprising:
a) operating the plasma source to generate an inductively coupled plasma in the upper chamber while ceasing to supply RF power to the bias unit, such that ions from the plasma are blocked by the GIF and only neutrals from the plasma are allowed to pass through the GIF and modify a surface of the substrate in the lower chamber;
b) introducing an inert gas into the lower chamber and operating the bias unit to supply RF power to the bias unit, thereby igniting a plasma in the lower chamber and converting it into a CCP reactor, wherein ions from the plasma are accelerated towards the substrate to remove the modified surface layer;
c) repeating the surface modification and the sputtering steps until the targeted layer of the material is removed; and
performing a radical-based HSE process, comprising:
a) introducing a gas or a precursor to the upper chamber;
b) operating the plasma source to generate an inductively coupled plasma in the upper chamber while ceasing to supply RF power to the bias unit, such that ions from the plasma are blocked by the GIF and neutrals from the plasma are allowed to pass through the GIF and modify the surface of the mask in the lower chamber and subsequently remove the one or plurality of layers for the mask.

19. The method of claim 18, wherein the mask materials include one or a combination of the following materials: carbon, metal-doped carbon, silicon, silicon nitride, silicon oxide, photoresist, titanium nitride.

20. The method of claim 18, wherein radical-based HSE further employs halogen, oxygen, hydrogen, and carbon-fluorine compounds.
